(19) United States
(12) Patent Application Publication
(10) Pub. No.: US 2015/0245529 A1
(43) Pub. Date: Aug. 27, 2015

(54) MEMORY INSERTION TOOL

(71) Applicant: HEWLETT-PACKARD DEVELOPMENT COMPANY, L.P., Houston, TX (US)

(72) Inventors: Kin Tam, Roseville, TX (US); Henry Guillen, Houston, TX (US); Kevin F. Labbe, Houston, TX (US); Stuart P. Rush, Houston, TX (US)

(21) Appl. No.: 14/431,019

(22) PCT Filed: Dec. 20, 2012
(86) PCT No.: PCT/US2012/070839

§ 371 Date: Mar. 25, 2015

(51) Int. Cl. H05K 7/14; H05K 13/00; H05K 13/04

(52) U.S. Cl. CPC H05K 7/1415; H05K 13/0447; H05K 13/0053

(57) ABSTRACT

Embodiments of the present invention disclose a tool for inserting a memory module. According to one embodiment, the memory insertion tool includes an elongated guide member and a pair of engagement handles formed on opposite ends of an upper surface of the guide member. Moreover, the bottom surface of the guide member is continuously flat and includes a beveled inner area for receiving the memory module.

### BACKGROUND

Transportation of computers and similar equipment to some regions of the world may subject such devices to extremely rough conditions including extensive shock and vibrations. As a result, there lies a great potential for damage or connectivity issues for certain internal processing components associated with the computer, such as a motherboard or printed circuit board (PCB) for example, during extended transportation routes.

One such processing component includes a dual in-line memory module (DIMM). More particularly, a DIMM socket connector provides electrical connection between the motherboard of the computing device and a DIMM card. However, rough transportation conditions may exert enough force on the DIMM socket connector to cause the DIMM card to dislodge, thus creating marginal or poor electrical contact between the DIMM card and the socket pins of the DIMM socket connector. Such a situation may cause the computer to fail either immediately upon first boot or soon thereafter. Thus, proper insertion of the DIMM at the time of manufacturing the computing device is of prime importance.

### BRIEF DESCRIPTION OF THE DRAWINGS

The features and advantages of the inventions as well as additional features and advantages thereof will be more clearly understood hereinafter as a result of a detailed description of particular embodiments of the invention when taken in conjunction with the following drawings in which:

FIG. 1 is a three-dimensional top view of the memory insertion tool and memory module according to an example of the present invention.

FIG. 2 is a three-dimensional bottom view of the memory insertion tool and memory module according to an example of the present invention.

FIGS. 3A and 3B are side profile views of the memory insertion tool and memory module in accordance with an example of the present invention.

FIGS. 4A and 4B are three-dimensional views of an operating environment in which a user utilizes the memory insertion tool for setting a memory module within a socket connector in accordance with an example of the present invention.

FIGS. 5A-5C are simplified illustrations of an operating environment and procedure in which an installer places a memory module within a socket connector and utilizes the insertion tool to complete the setting process in accordance with one example of the present invention.

### DETAILED DESCRIPTION OF THE INVENTION

The following discussion is directed to various embodiments. Although one or more of these embodiments may be discussed in detail, the embodiments disclosed should not be interpreted, or otherwise used, as limiting the scope of the disclosure, including the claims. In addition, one skilled in the art will understand that the following description has broad application, and the discussion of any embodiment is meant only to be an example of that embodiment, and not intended to intimate that the scope of the disclosure, including the claims, is limited to that embodiment. Furthermore, as used herein, the designators “A”, “B” and “N” particularly with respect to the reference numerals in the drawings, indicate that a number of the particular feature so designated can be included with examples of the present disclosure. The designators can represent the same or different numbers of the particular features.

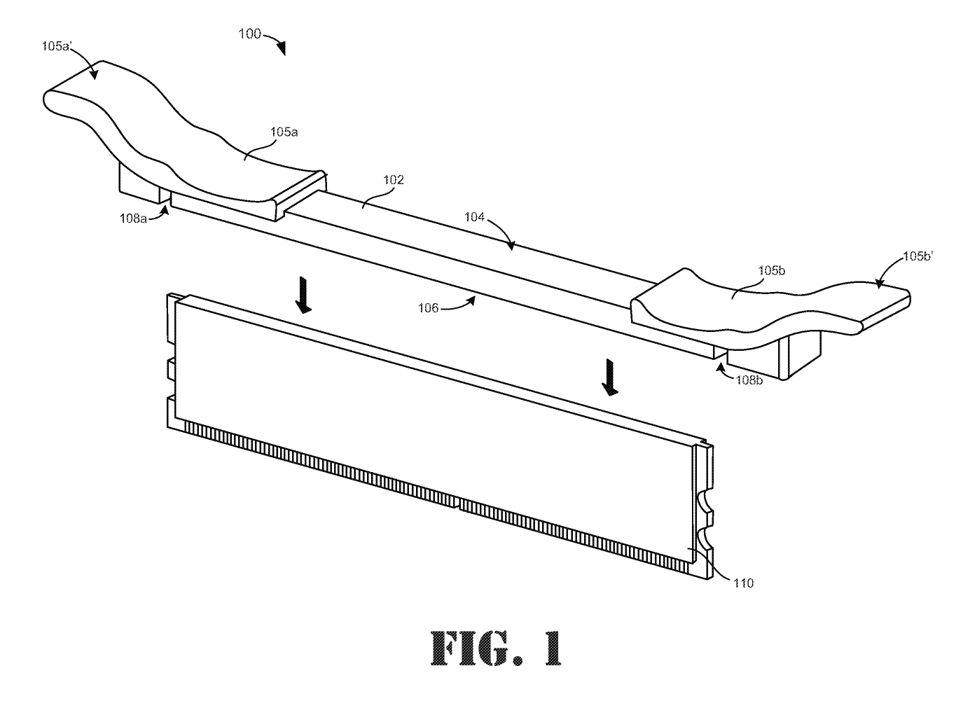

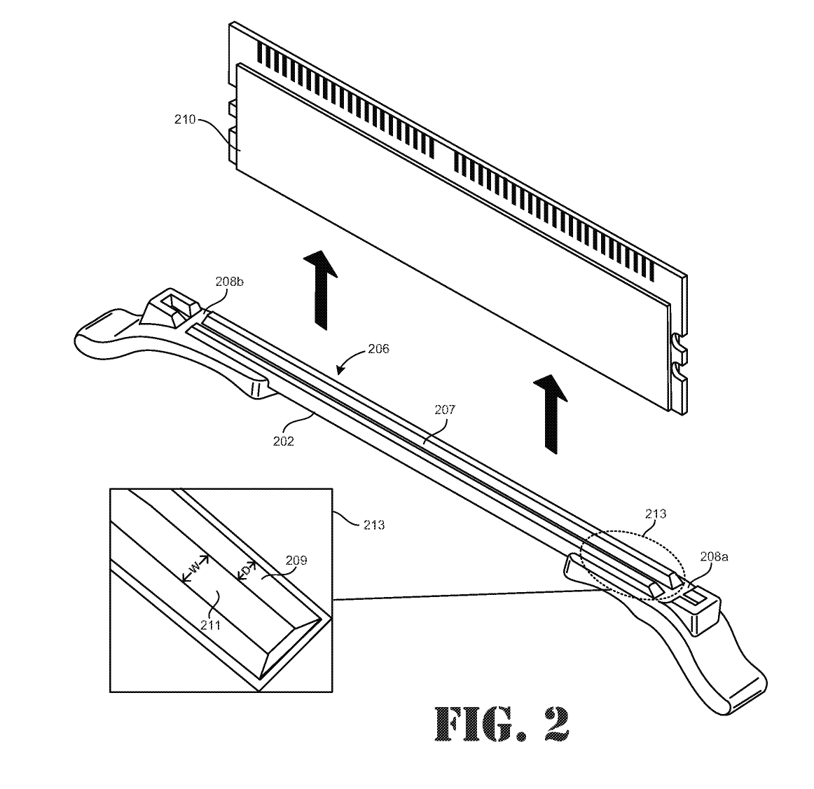

The figures herein follow a numbering convention in which the first digit or digits correspond to the drawing figure number and the remaining digits identify an element or component in the drawing. Similar elements or components between different figures may be identified by the user of similar digits. For example, 143 may reference element “43” in FIG. 1, and a similar element may be referenced as 243 in FIG. 2. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense.

As explained above, memory failures are not always caused by defective components from the manufacturer. Memory-related failures can often be attributed to improper handling, contaminant accumulation, and/or a lack of knowledge of proper insertion techniques. Factory builders use their thumbs and sustain injury due to the sharp edge of memory modules (average minimum insertion force of over twenty pounds distributed on the memory module's upper surface area of only one-sixteenth of an inch). Improper handling between the memory trays to the system socket may cause contamination and component damage. Furthermore, the memory module sometimes undergoes multiple insertions—often attributed to a user's attempt to avoid the pain of manual insertion—thus causing contaminants to form due to the continuous scraping of the socket walls by the memory module.

Prior solutions to the aforementioned problems include bulky memory insertions tools that include high profile designs, which may cause the memory module to waddle and bend thereby possibly damaging both the memory module and board. Still further, factory workers sometimes attempt to alleviate the problem by inserting one side of the memory module into a connector followed by the other side in a back and forth motion. Such rocking motion may cause damage to both the electrical contacts of the DIMM and connector portion as the memory module is unevenly and jaggedly inserted into the socket connector.

Examples of the present invention disclose a low profile insertion tool for use on memory module partially seated on the system board. According to one embodiment, the user/builder may use the tool to properly apply even pressure on the surface of the memory module to prevent connector and memory module damage caused by improper insertion. Furthermore, the tool includes an inner beveled area and a pair of engagement handles that provide an effective memory insertion technique and helps prevent contaminants caused by multiple insertions due to improperly seated memory modules.

Referring now in more detail to the drawings in which like numerals identify corresponding parts throughout the views, FIG. 1 is a three-dimensional top view of the memory insertion tool and memory module according to an example of the present invention. As shown here, the memory insertion tool 100 includes an elongated guide member 102 having a pair of extended gripping or engaging handles 105a and 105b. The guide member 102 may be formed of synthetic injection molded plastic with electrostatic discharge (ESD) properties. Alternatively, the guide member 102 may be comprised of a metallic material that includes a safe rubberized coating in order to reduce overall thickness of the tool. The guide member 102 includes a lower surface 106 (surface opposite upper surface 104) configured to rest on top of the memory module 110. According to one example, the engaging handles 105a and 105b are welded on the guide member and have substantially flat topmost surface areas 105a′ and 105b′. Additionally, the engaging handles 105a and 105b are formed directly on the upper surface of the guide member 102 so as to create a low profile form factor for the insertion tool 100. The engaging handles 105a and 105b are utilized by an installer or user to apply pressure (via fingers) when installing a partially-set memory module (i.e., memory module previously and partially inserted into socket connector). In one example, the lower surface 106 of the guide member 102 also includes two indentations 108a and 108b, which provide additional support for the guide member 102 when pressure is applied on the engaging handles 105a and 105b during setting of the memory module 110. Still further, the insertion tool 100 may be plastic or rubber-coated in order to prevent damage should the tool drop on the mother board while also serving to provide a less rigid and more comfortable material for the installer when applying pressure thereon.

FIG. 2 is a three-dimensional bottom view of the memory insertion tool and memory module according to an example of the present invention. As shown, this particular example embodiment depicts an underside area 206 of the elongated guide member 202. More specifically, the underside 206 of the guide member 202 includes a beveled area 207 for receiving the memory module 210. That is, the inner beveled area 207 of the guide member 202 is used as a small rail to guide the memory module during the insertion or setting process. Moreover, the enlarged view 213 of the beveled area 207 illustrates that the width of the width (W) of the beveled inner area is substantially equal to or greater than the depth (D) of the beveled area. Such a configuration helps to prevent the guide rails 207 from undesirably rubbing against components near the top of the memory module. According to one example embodiment, the beveled area 207 is comprised of a non-metallic material in order to prevent chaffing of the memory module 210 during the setting process.

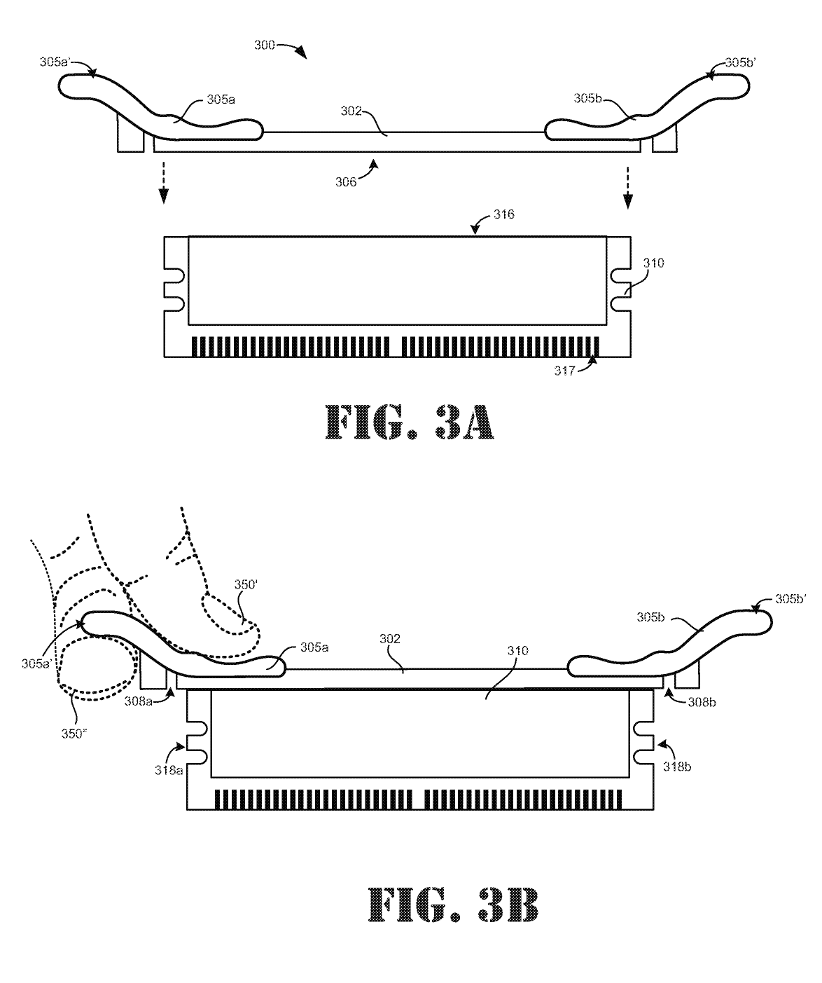

FIGS. 3A and 3B are side profile views of the memory insertion tool and memory module in accordance with an example of the present invention. FIG. 3A depicts the memory insertion tool 300 being placed over the memory module 310 to be set. As shown here, the bottom surface 306 of the guide member 302 is lowered onto the top surface 316 (opposite electrical contact surface 317) of the memory module 310. The insertion tool 300 is lowered via a user or installer handling the pressure input portions 305a and 305b. Moreover, these pressure input portions 305a and 305b serve to provide stability and eliminate the risk of dropping the tool—potentially damaging the system board or memory module components—while transporting the tool to and from various memory modules. According to one example, formation of the pressure input portions 305a and 305b begins near a central area (e.g., one inch away from midpoint) of the guide member 302 and extends diagonally upwards and away from outer edges of the guide member 302 while rounding into a substantially flat upper and lower surface areas 305a′ and 305b′ at its topmost point. As shown in FIG. 3B, the shape and size of the pressure input portions 305a and 305b provides a unique balance of surface area, allowing for comfortable and ergonomic insertion points for an installer's thumb 550′ and index finger 550″, and length, allowing for sufficient and even pressure to be applied onto the memory module 310. FIG. 3B depicts the insertion tool 300 and guide member 302 being lowered to lie immediately adjacent and in physical contact with the upper edge 316 of the partially-set memory module 310. Furthermore, since the bottom area 306 of the guide member 302 is continuously flat, an installer may easily and quickly move from one memory module to the next installation, thereby increasing productivity within the factory. In addition, when the module is centrally-aligned within the beveled area of the guide member 302, indentations 308a and 308b formed within the guide member 302 are positioned near outer edges 318a and 318b of the memory module 310. As mentioned above, the position of the indentations 308a and 308b serves to prevent excessive load being placed on the memory module 310 while also preventing damage to the tool (e.g., snapping due to excessive pressure).

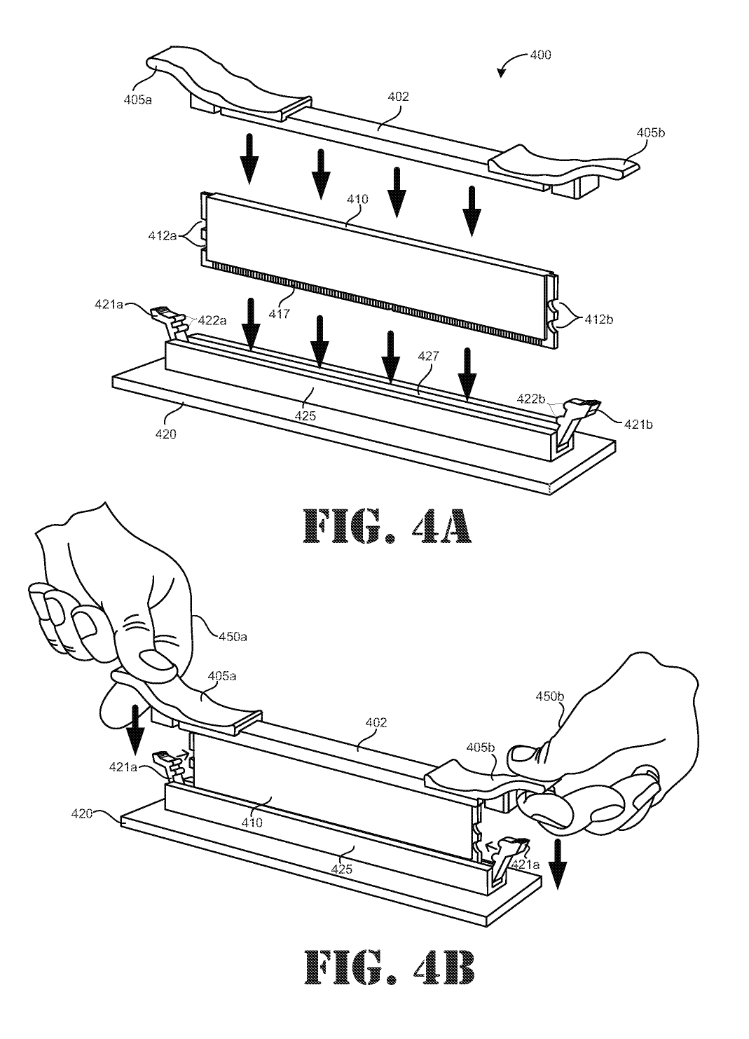

FIGS. 4A and 4B are three-dimensional views of an operating environment in which a user utilizes the memory insertion tool for setting a memory module within a socket connector in accordance with an example of the present invention. As shown in FIG. 4A, the insertion tool 405a is placed over a memory module 410, which is to be fully-inserted and set within a socket connector 425. According to one example embodiment, the memory module 410 is partially-set within the socket connector 425 and base 420 prior to using the insertion tool 400. That is, a lower area of memory module (including electrical contacts 417) is placed comfortably within the socket cavity 427 of the socket connector 425. The insertion tool 400 may then be used by an installer to apply sufficient force onto the top edge of memory module so as to completely set the memory module 410 within the socket connector 425. FIG. 4B depicts an installer using their hands 450a and 450b to apply downward pressure onto memory module 410 using the engagement handles 405a and 405b and guide member 402. Since even pressure is applied on the entire top edge of the memory module 410 via the engagement handles 405a and 405b, these memory modules may be properly installed and securely set within the socket connector 425 without pain or discomfort to the installer hands or fingers (450a and 450b). Once the memory module is properly set with the socket connector 425, clamps 421b and 421a associated with the socket connector 425 may be used to lock the memory module within the socket connector 425 through engagement of protruding portions 422a and 422b with notches 412a and 412b of the memory module 410.

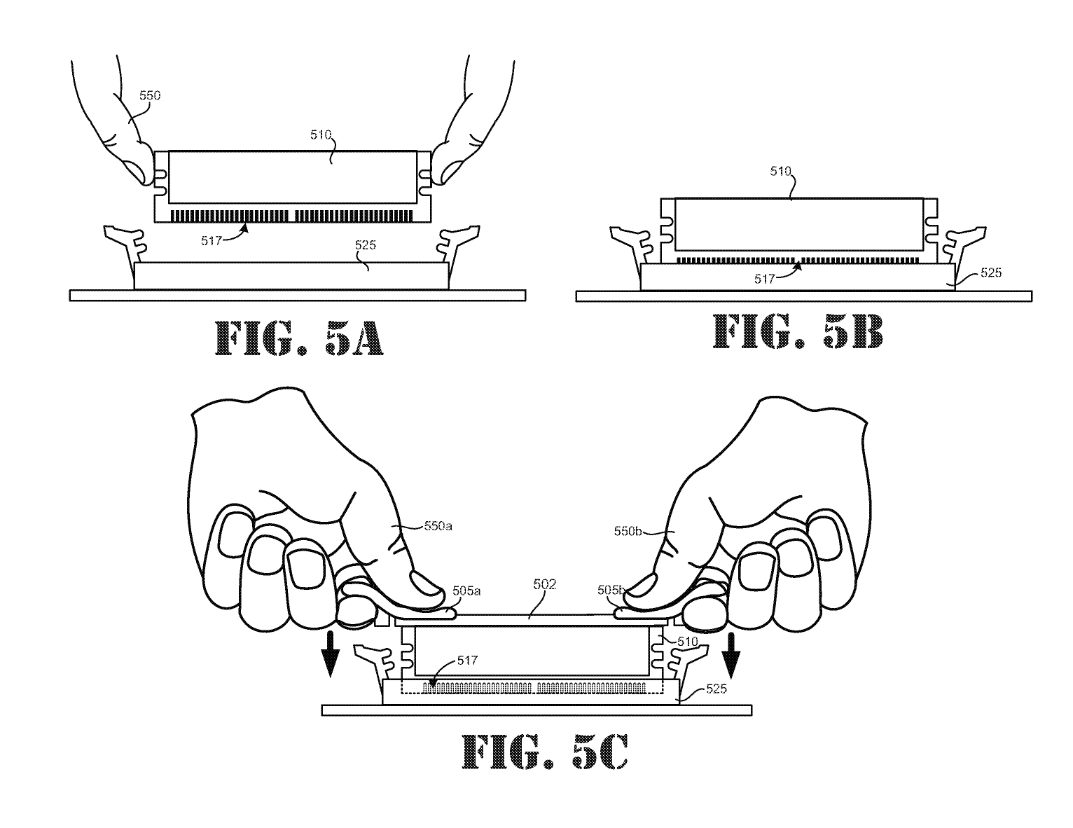

FIGS. 5A-5C are simplified illustrations of an operating environment and procedure in which an installer places a memory module within a socket connector and utilizes the insertion tool to complete the setting process in accordance with one example of the present invention. FIG. 5A depicts a user or installer 550 placing a memory module 510 within a socket connector 525. More particularly, the electrical contacts 517 of the memory module 510 are lowered into a receiving area of the socket connector 525. Thereafter, FIG. 5B illustrates the memory module 510 as partially-set within the socket connector 525. As shown here, the electrical contacts 517 of the memory module 510 are only partially-inserted (i.e., contacts 517 still visible) into the socket connector 525 and thus additional force is still required in order for the memory module to be fully set within the socket connector 525. Next, FIG. 5C depicts the operator utilizing the insertion tool 502 to apply downward force (as indicated by directional arrows) onto the memory module 510 so as to complete the setting and installation process. More specifically, the user's hands 550a and 550b engage and grip respectively engagement handles 505a and 505b of the insertion tool 502 so as to push the memory module 510 further into the socket connector 525. As mentioned above, the shape and size of the handle portions 505a and 505b are conducive for a comfortable grip when properly held between the user's thumb (resting on handle' upper surface) and index finger (resting on handle's lower surface). Consequently, the memory module 510 may be fully-inserted into the socket connector 525 such that the electrical contacts 517 of the memory module 510 are no longer visible to the user.

Embodiments of the present invention provide a memory insertion tool for a dual-in line memory module (DIMM). Moreover, many advantages are afforded by the memory insertion described in accordance with embodiments of the present invention. For instance, the insertion tool described here is simple to use unlike the more complex and unwieldy tools of prior solutions. In addition, the low form factor design gives the installer greater sensitivity to the amount of pressure being used during the setting process. Still further, the memory insertion tool of the present examples is durable and reusable and also helps to reduce the presence of surface contaminants on the memory module due to repeated insertion attempts.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement o order of elements or other features illustrated in the drawings or described herein need not be arranged in the particular way illustrated and described. Many other arrangements are possible according to some embodiments.

The techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the techniques

What is claimed is:

1. A memory insertion tool comprising:
an elongated guide member; and
a pair of engagement handles formed directly on opposite ends of an upper surface of the guide member,
wherein a bottom surface opposite the upper surface of the guide member is continuously flat and includes a beveled inner area for receiving a memory module.

2. The memory insertion tool of claim 1, wherein the engagement handles include flat upper surface areas utilized by an installer for gripping and applying pressure onto the tool when inserting an attached memory module into a socket connector.

3. The memory insertion tool of claim 2, wherein the lower surface of the guide member includes indentations formed near each end of the guide member.

4. The memory insertion tool of claim 3, wherein the indentations are formed near outer edges of the memory module when the memory module is positioned centrally within the beveled inner area of the guide member.

5. The memory insertion tool of claim 3, wherein a width of the inner beveled area is substantially equal to or greater than the depth of the inner beveled area.

6. The memory insertion tool of claim 5, wherein the pair of engagement handles extend upwards and away from each respective end of the elongated guide member.

7. The memory insertion tool of claim 1, wherein the elongated guide member is comprised of a synthetic injection molded plastic with electrostatic discharge (ESD) properties.

8. The memory insertion tool of claim 1, wherein the elongated guide member is comprised of a metallic material having a rubberized coating.

9. A tool for applying even insertion force on a memory, the tool comprising:
an elongated guide member having an upper surface and a lower surface opposite the upper surface, wherein the lower surface is continuously flat and includes a beveled inner area for receiving the memory module; and
a first pressure input portion and second pressure input portion formed directly on opposite ends along the upper surface of the guide member.

10. The tool of claim 9, wherein the first pressure input portion and second pressure input portion include flat upper surface areas used by an installer for gripping and applying pressure onto the tool when inserting an attached memory module into a socket connector.

11. The tool of claim 9, wherein the lower surface of the guide member includes indentations formed near each end of the guide member.

12. The tool of claim 11, wherein the indentations are formed near outer edges of the memory module when the memory module is positioned centrally within the beveled inner area of the guide member.

13. The tool of claim 11, wherein a width of the inner beveled area is substantially equal to or greater than the depth of the inner beveled area.

14. The tool of claim 12, wherein both the first pressure input portion and the second pressure input portion extend upwards and away from each respective end of the elongated guide member.

15. A memory insertion tool for setting a memory module within a socket connector, the insertion tool comprising:
an elongated guide member having an upper surface and a bottom surface opposite the upper surface; and
a pair of engagement portions that extend upwards and away from opposite ends of the elongated guide member and are formed directly on the upper surface of the guide member, wherein the engagement portions include substantially flat surface areas used by the installer for applying pressure onto the tool when inserting an attached memory module into a socket connector,
wherein a bottom of the guide member is continuously flat and includes a beveled inner area for receiving a memory module, wherein a width of the inner beveled area is substantially equal to or greater than the depth of the inner beveled area, and
wherein the bottom surface of the guide member includes indentations formed near each end of the guide member so as to substantially align with outer edges of a memory module when the memory module is positioned centrally within the beveled inner area of the guide member.
